(19) United States
(12) Patent Application Publication
(10) Pub. No.: US 2012/0261182 A1
(43) Pub. Date: Oct. 18, 2012

(54) LIQUID-REPELLENT, LARGE-AREA, ELECTRICALLY-CONDUCTING POLYMER COMPOSITE COATINGS

(75) Inventors: Constantine M. Megaridis, Oak Park, IL (US); Ilker S. Bayer, Arnesano (IT); Manish K. Tiwari, Zurich (CH); Arindam Das, Chicago, IL (US)

(73) Assignee: The Board of Trustees of the University of Illinois, Urbana, IL (US)

(21) Appl. No.: 13/156,908

(22) Filed: Jun. 9, 2011

Related U.S. Application Data
(60) Provisional application No. 61/353,097, filed on Jun. 9, 2010.

(51) Int. Cl. H05K 9/00; B32B 27/30; H01B 1/24; B05D 5/12; B82Y 30/00

(52) U.S. Cl. 174/388; 252/511; 427/122; 428/422; 977/773; 977/788; 977/779

(57) ABSTRACT

A polymeric composition including a blend of poly(vinylidine fluoride) (PVDF), poly(methyl methacrylate) (PMMA), carbon nanofibers, and poly(tetrafluoroethylene) (PTFE) particles is described and claimed. The polymeric composition may be coated onto a substrate and dried to form a film adhered to the substrate. The film optionally exhibits an electrical conductivity of about 10 Siemens per meter (S/m) to about 310 S/m and an electromagnetic interference shielding of about 32 decibels. Further, a coated substrate is provided including a substrate and a film adhered to the substrate, where the film includes a polymeric composition comprising a blend of PVDF, PMMA, carbon nanofibers, and PTFE particles.

### CROSS REFERENCE TO RELATED APPLICATIONS

This application claims the benefit of U.S. provisional application Ser. No. 61/353,097 filed Jun. 9, 2010, which is incorporated herein by reference in its entirety.

### TECHNICAL FIELD OF THE INVENTION

This invention is related to the area of liquid-repellent, electrically-conducting polymer composites including poly(vinylidine fluoride) (PVDF). In particular, it relates to PVDF polymer composites comprising PVDF, poly(methyl methacrylate) (PMMA), and fillers. These composites show good performance as Electromagnetic Interference (EMI) shielding materials in a wide frequency range extending into the Terahertz regime.

### BACKGROUND OF THE INVENTION

A few examples of technological applications for which metal-based materials have been almost exclusively considered to this date include electrostatic dissipation, microwave absorption and electromagnetic interference (EMI) shielding of sensitive electrical/electronic circuitry and devices, antenna systems, aerospace and military equipment (e.g. lightning-protection aircraft composite panels), stealth technology, radar absorbing materials, and avionics line replaceable unit (LRU) enclosures.

A report of superhydrophobic, conductive, polymer-based coatings was made by Zhu et al. [1] disclosing electrospun stable, polyaniline/polystyrene, large-area films well suited for corrosive environments. The conductivities of the reported films are too low (i.e., 10⁻² Siemens per meter (S/m)), however, for EMI shielding. Han et al. [2] created transparent, conductive and superhydrophobic films using carbon nanotube/silane sol solutions. The films disclosed by Han include high-quality nanotubes having diameters of 3 to 5 nanometers, which result in a high cost to prepare the coatings. Luo et al. [3] used solution processing and vacuum filtering to produce superhydrophobic carbon nanotube/Nafion nanocomposite films having conductivities up to 1700 S/m, which were maintained even after 1000 bending cycles. However, the films were formed on filtration membranes, thus their transfer and adherence to other surfaces might pose challenges. Meng and Park [4] applied transparent, conductive, superhydrophobic films on glass using fluoropolymer grafted multiwall carbon nanotubes. Similar to Han, the high quality of the carbon nanotubes prevents such a process from being low-cost. Zou et al. [5] synthesized polymer-based superhydrophobic coatings with very high conductivities in the range 3×10³-10⁴ S/m (as compared to a conductivity of 6×10⁷ S/m for Ag); these coatings were created by a one-step solution casting process that involved a carbon-nanotube-conjugated block copolymer dispersion. Attractive features of this method include the ability to apply on various substrates ranging from glass and silica wafers, to metals, fabrics or even paper. Again, however, the high cost of carbon nanotubes having diameters of 10 to 20 nanometers hinders scale-up to large-area applications.

The EMI shielding effectiveness of a material depends not only on its conductivity but also its permeability [6], therefore EMI shielding does not correlate directly with conductivity. Furthermore, EMI shielding effectiveness varies with frequency [7], thus requiring EMI measurements to be performed over a frequency range or the entire spectrum, when necessary. EMI shielding properties, such as shielding effectiveness (SE), of pure materials or composites containing conductive fillers depends on various factors, such as synthesis technique, filler particle size, length scale of conductive elements, filler conductivity, magnetic property, chemical treatments, crystallinity, etc. Most of the materials studied for their SE are metal fibers, carbon nanotubes or nanofibers of varying morphologies, and metal coated fibers.

Though metals offer superior EMI shielding due to their high electrical conductivity, the possibilities of chemical corrosion along with their high density restrict their use in many applications. Filamentous carbon materials, on the other hand, due to their chemical inertness, low production costs and the relatively low particle loadings required for sufficiently large SE, may offer an attractive choice for EMI shielding applications. For example, polymer composites containing vapor-grown carbon nanofibers (CNFs) have been studied at frequencies 15 MHz-75 GHz, with maximum SE within this frequency zone around 30-50 dB for 1 mm-3 mm thick samples [8]. CNF-loaded polymer composites about 100 μm-thick displayed SE of up to 25 dB in the X-band (i.e., 8.2 GHz to 12.4 GHz) [9]. Details of the SE of various particle-filled composite materials are given in a recent review [10].

Electromagnetic waves in the terahertz frequency range (i.e., 0.1-10 THz, or alternatively referred to as 100-10,000 GHz) have remained the least explored and developed in the entire spectrum, thus creating the “THz gap.” In recent years, there has been unprecedented growth in the development of terahertz devices, circuits and systems due to their promising applications in astronomy, chemical analysis, biological sensing, imaging and security screening [11-15]. THz sources based on Schottky diodes and quantum cascade lasers (QCL) currently provide plenty of output power, covering a broad frequency range [16-18]. Improvements in transistor technology also have enabled the demonstration of THz amplifiers and integrated circuits up to 300 GHz [19]. It has been predicted that THz-based communication systems with data rates of 5-10 gigabits per second (Gb/s) or higher will replace today's wireless LAN systems in 10 years [20].

With the increasing speed of the above electronic circuits and systems, EMI shielding in the THz region is becoming more important [21-22]. THz EMI shielding may also find applications in security and defense to protect information detectable by THz imaging and sensing techniques. In addition, effective THz attenuation devices are required in many quasi-optical systems (e.g. THz spectroscopy and imaging), where little research has been done to date. Therefore, innovations in materials and processes for EMI shielding and attenuation of THz electronic devices are of immense interest for advanced technology applications.

Poly(vinylidine fluoride) (PVDF) is a polymer with exceptional chemical resistance, thermal stability and outstanding dielectric and piezoelectric properties, which justify its widespread use in many industries, for example as ultrafiltration and microfiltration membrane materials, in lithium ion batteries, and in developing organic/inorganic or all-organic electro-mechanical composite materials. PVDF is characterized by having a repeating monomer of the following structure: —[CH₂—CF₂]

In applications where surface adhesion is critical, however, use of PVDF poses a severe challenge due to its inherent hydrophobicity and chemical inertness against functionalization. Furthermore, due to its chemical inertness and poor adhesion characteristics, dispersion of functional fillers in PVDF is poor. Although polymer blending in solution is an easy and cost-effective technique, insolubility of PVDF in many common solvents hinders its potential use in polymer composites. In order to facilitate practical applications in the coatings industry, the search for materials for effectively enhancing adhesion, pigment dispersion, and morphological and piezoelectric properties of PVDF is ongoing.

One challenge to providing cost-effective EMI shielding polymeric systems comprising PVDF is the need for the inclusion of one or more conductive materials that are necessary for EMI shielding, preferably over a wide range of frequencies. Accordingly, there is a need in the art to develop a formulation that will allow successful large-area EMI shielding employing a polymer composite, which is also liquid-repellent.

### SUMMARY OF THE INVENTION

An embodiment of the invention is a polymeric composition comprising a blend of poly(vinylidine fluoride) (PVDF), poly(methyl methacrylate) (PMMA), carbon nanofibers, and poly(tetrafluoroethylene) (PTFE) particles.

Another aspect of the invention is a method for making a polymeric film comprising providing a polymeric composition comprising poly(vinylidine fluoride) (PVDF), poly(methyl methacrylate) (PMMA), carbon nanofibers, and poly(tetrafluoroethylene) (PTFE) particles, coating the composition onto a substrate, and drying the composition to form the polymeric film on the substrate.

A further aspect of the invention is a coated substrate comprising a substrate and a film adhered to the substrate, the film comprising a polymeric composition comprising a blend of poly(vinylidine fluoride) (PVDF), poly(methyl methacrylate) (PMMA), carbon nanofibers, and poly(tetrafluoroethylene) (PTFE) particles.

These and other embodiments will be apparent to those of skill in the art upon reading the specification.

### BRIEF DESCRIPTION OF THE DRAWINGS

FIG. 1 is a graph of water sessile contact angle on (PVDF+PMMA)/PTFE dried coatings with changing PTFE content, the latter expressed in terms of PTFE/(PVDF+PMMA) weight ratio.

FIG. 2 is a graph of electrical conductivity and sessile water contact angle for various (PVDF+PMMA)/PTFE/CNF composite coatings as a function of CNF loading expressed in terms of CNF/(PVDF+PMMA) weight ratio, and having a PTFE/(PVDF+PMMA) weight ratio of 5.76.

FIG. 3 is a graph of water droplet roll-off angle on (PVDF+PMMA)/PTFE/CNF coatings with different CNF loadings expressed in terms of CNF/(PVDF+PMMA) weight ratio, and having a PTFE/(PVDF+PMMA) weight ratio of 5.76.

FIG. 4a is scanning electron micrograph of a (PVDF+PMMA)/PTFE/CNF coating having a CNF loading of 0.068. The scale bar corresponds to 50 μm.

FIG. 4b is a scanning electron micrograph of a (PVDF+PMMA)/PTFE/CNF coating having a CNF loading of 0.068. The scale bar corresponds to 2 μm.

FIG. 4c is a scanning electron micrograph of a (PVDF+PMMA)/PTFE/CNF coating having a CNF loading of 1.1. The scale bar corresponds to 50 μm.

FIG. 4d is a scanning electron micrograph of a (PVDF+PMMA)/PTFE/CNF coating having a CNF loading of 1.1. The scale bar corresponds to 2 μm.

FIG. 5 illustrates a two-port network schematic defining the quantities used in the definition of the S parameters.

FIG. 6 illustrates an experimental setup implementing the schematic of FIG. 5. The dried coating sample is fully encased at the coupling of the two waveguides, to ensure minimal outside interference.

FIG. 7a is a graph of S parameters, S₁₁ (reflection) and S₂₁ (transmission), for a (PVDF+PMMA)/PTFE/CNF coating with a CNF loading of 0.138 in the 8.2-12.4 GHz frequency range (X-band), as obtained by means of the two-port measurement setup shown in FIG. 6.

FIG. 7b is a graph of S parameters, S₁₁ (reflection) and S₂₁ (transmission), for a (PVDF+PMMA)/PTFE/CNF coating with a CNF loading of 0.921 in the 8.2-12.4 GHz frequency range (X-band), as obtained by means of the two-port measurement setup shown in FIG. 6.

FIG. 8a is a graph of S parameters, S₁₁ (reflection) and S₂₁ (transmission), for a (PVDF+PMMA)/PTFE/CNF coating with a CNF loading of 0.068 in the 8.2-12.4 GHz frequency range (X-band), as obtained by means of the two-port measurement setup shown in FIG. 6.

FIG. 8b is a is a graph of S parameters, S₁₁ (reflection) and S₂₁ (transmission), for a (PVDF+PMMA)/PTFE/CNF coating with a CNF loading of 0.138 in the 8.2-12.4 GHz frequency range (X-band), as obtained by means of the two-port measurement setup shown in FIG. 6.

FIG. 8c is a is a graph of S parameters, S₁₁ (reflection) and S₂₁ (transmission), for a (PVDF+PMMA)/PTFE/CNF coating with a CNF loading of 0.281 in the 8.2-12.4 GHz frequency range (X-band), as obtained by means of the two-port measurement setup shown in FIG. 6.

FIG. 8d is a is a graph of S parameters, S₁₁ (reflection) and S₂₁ (transmission), for a (PVDF+PMMA)/PTFE/CNF coating with a CNF loading of 0.587 in the 8.2-12.4 GHz frequency range (X-band), as obtained by means of the two-port measurement setup shown in FIG. 6.

FIG. 8e is a is a graph of S parameters, S₁₁ (reflection) and S₂₁ (transmission), for a (PVDF+PMMA)/PTFE/CNF coating with a CNF loading of 0.921 in the 8.2-12.4 GHz frequency range (X-band), as obtained by means of the two-port measurement setup shown in FIG. 6.

FIG. 8f is a is a graph of S parameters, S₁₁ (reflection) and S₂₁ (transmission), for a (PVDF+PMMA)/PTFE/CNF coating with a CNF loading of 1.1 in the 8.2-12.4 GHz frequency range (X-band), as obtained by means of the two-port measurement setup shown in FIG. 6.

FIG. 9 is a graph of the variation of reflected and transmitted power (% of input power) with CNF loading in (PVDF+PMMA)/PTFE/CNF composite coatings.

FIG. 10 is a scanning electron micrograph of a (PVDF+PMMA)/PTFE/CNF coating with a CNF loading of 1.1 expressed as CNF/(PVDF+PMMA) weight ratio.

FIG. 11 is a graph of electrical conductivity and average power transmission for EM frequencies in the range 570-630 GHz, for (PVDF+PMMA)/PTFE/CNF coatings with varying CNF loading. In all cases, the PTFE/polymer weight ratio was 5.76. Although the dried coatings used to produce this graph had the same composition as those in FIG. 2, the conductivities differed because the solvent system was not the same.

FIG. 12 is a graph of sessile water contact angle and roll-off angle for various (PVDF+PMMA)/PTFE/CNF composite coatings as a function of CNF loading expressed in terms of CNF/(PVDF+PMMA) weight ratio. In all cases the PTFE/polymer weight ratio was 5.76. The roll-off values indicate self-cleaning ability (values below 10 deg, causing water droplets to roll off and clean the surface)

FIG. 13 is a high resolution transmission electron microscope image of as-grown CNF produced at 1100° C./PR-24-XT-LHT Pyrograph III. (Image provided by Applied Sciences Inc. and reproduced with permission.)

FIG. 14a is a transmission electron microscope (TEM) image of heat treated hollow-core CNF (PR-24-XT-HHT Pyrograph III), typical of those used in the present (PVDF+PMMA)/PTFE/CNF coatings. The square area is enlarged in FIG. 14b.

FIG. 14b is a high resolution TEM magnification detail of the square area marked in FIG. 14a obtained from a heat treated, hollow-core CNF (PR-24-XT-HHT Pyrograph III), typical of those used in the present (PVDF+PMMA)/PTFE/CNF coatings. The square area is enlarged in FIG. 14c.

FIG. 14c is a high resolution TEM detail of the square area marked in FIG. 14b obtained from a heat treated, hollow-core CNF (PR-24-XT-HHT Pyrograph III), typical of those used in the present (PVDF+PMMA)/PTFE/CNF coatings.

### DETAILED DESCRIPTION OF THE INVENTION

It would be desirable to provide polymer-based films (i.e., dried coatings) that are capable of electromagnetic interference (EMI) shielding for large areas. In response to this need, novel superhydrophobic and conductive, polymer-based compositions and films are provided. More particularly, low cost liquid-repellent, electrically-conductive composite compositions are provided, comprising carbon nanofibers and PTFE fillers dispersed in a hydrophobic polymer matrix and applied to substrates by spray. It was discovered that polymer composite compositions could be prepared that, upon application to substrates and drying to form films, exhibit properties of not only liquid-repellency but also EMI shielding over multiple frequency ranges, including THz frequencies. The compositions and methods utilize only solution-processable and commercially available raw materials, and are therefore low-cost.

As noted above, poly(vinylidine fluoride) (PVDF) is a polymer with exceptional chemical resistance, thermal stability and outstanding dielectric and piezoelectric properties, which justify its widespread use in many industries, and is characterized by having a repeating monomer of the following structure: —[CH₂—CF₂]—. The inherent hydrophobicity and chemical inertness against functionalization properties of PVDF result in poor adhesion of PVDF to substrates and dispersion of functional fillers in PVDF. A suitable solvent for PVDF, for example and without limitation, comprises dimethylformamide (DMF). DMF is the solvent almost universally used in processing PVDF, and is employed in embodiments of the polymeric composites disclosed herein.

Blends of PVDF with suitable acrylic resins have been developed, which improve PVDF's pigment wetting and coating adhesion. Acrylic resins can be chosen from any of the following classes of polymers: Polyalkyl(meth)acrylates and polyalkylcyanoacrylates such as poly(methyl methacrylate) (PMMA), polyethylmethacrylate, polybutylmethacrylate, polyethylcyanoacrylate, and polyoctylcyanoacrylate, to name a few. For example, PMMA is miscible with PVDF in solution at any proportion. PMMA is a thermoplastic synthetic polymer methyl methacrylate. Methyl methacrylate has the following structure: CH₂═C(CH₃)COOCH₃. Free radical polymerization of methyl methacrylate at the carbon-carbon double bond results in the transparent polymer PMMA. A suitable solvent for PMMA, for example and without limitation, comprises acetone. Advantageously, acetone evaporates quickly and is employed in embodiments of the polymeric composites disclosed herein.

A two-component (i.e., PVDF+PMMA) polymer composite system has been developed and commercialized for outdoor applications. This composite system provides a combination of the excellent resistance of PVDF to extreme environmental conditions, such as ultraviolet light and humidity, and the enhanced adhesion of PMMA. However, PMMA is not an electro-mechanically active polymer. Thus, in applications where electro-mechanical properties of PVDF are critical, the presence of PMMA does not contribute to an electrically-conductive composite. The ratio of PVDF to PMMA is variable depending on the application. In certain embodiments, the ratio of PVDF: PMMA comprises 60:40.

It has been discovered that polymer composites comprising poly (vinylidene fluoride) (PVDF) and acrylic poly (methyl methacrylate) (PMMA), carbon nanofibers and PTFE may successfully be prepared and provide numerous beneficial characteristics. It has been reported that a low surface energy polymer matrix improves conductivity values and lowers the percolation threshold, which is the threshold at which long-range connectivity occurs. Thus, in addition to the presence of conducting CNFs, the low surface energy of the PVDF/PMMA blend used in the present compositions has a positive effect on the conductivity, and thus on the shielding effectiveness of the dried films. The semi-crystalline polymer PVDF also has a positive effect on lowering the percolation threshold. Moreover, it is believed that the presence of the PTFE particles in the compositions also contributes to conductivity through the volume exclusion effect [10]. Introduction of additional non penetrable and non-conductive particles into a composite system restricts the randomness of conductive fillers present in the composites, and through restricting the location of conductive fillers, facilitates a large number of percolating pathways. An increase in conductive pathways due to the presence of additional non penetrable and non-conductive particles thus results in higher conductance with a lower concentration of conductive filler. This effect is known as the volume exclusion effect. Consequently, there is synergy between the PVDF, PMMA, PTFE particles and CNFs to provide the EMI shielding properties of the inventive polymer composite compositions and films.

More particularly, processes and compositions have been developed for providing polymer composite compositions comprising PVDF, polyalkyl(meth)acrylates and polycyanoacrylates and fillers as a blend for coating on substrates, within a number of hours or even days after preparation. For instance, the polymer blends preferably survive at least several hours, following manufacture and prior to being mixed with fillers and applied as a coating on a substrate. Once added to the polymer blend, the fillers typically settle to the bottom of the composition upon standing for 10 minutes or more. However, the composition may easily be agitated to re-suspend the fillers prior to being applying to a substrate. Such survivability allows the inventive polymer composite compositions to be successfully employed for large-area applications under real-world conditions.

Polytetrafluoroethylene (PTFE) is a synthetic fluoropolymer that is most commonly known by the DuPont brand name of Teflon®. PTFE has numerous advantageous properties, including a low coefficient of friction, a high chemical resistance, and an extremely high melting point. According to embodiments of the invention, PTFE is employed as polymeric particles that have average particles of a sub-micron size, such as less than about 1 micrometer (μm) in diameter, optimally between about 200 nm and 300 nm. In aspects of the invention, for incorporation into a polymeric matrix, PTFE particles are sonicated in a suitable dispersing solvent (i.e., subjected to sound energy to agitate the particles in the solvent) before adding the particles to a solution comprising PVDF and PMMA. Suitable dispersing solvents include, without limitation, acetone and acetone/DMF mixtures.

In aspects of the invention, polymer composite films comprising a PVDF/PMMA blend and containing submicron PTFE particles exhibit superhydrophobicity. The characteristic “superhydrophobic” may be applied to a material having a static water contact angle greater than 150°. The dried polymeric composite coatings described herein achieve such high static water contact angles by the presence of a hierarchical roughness structure spanning from micro to nano-scale sizes, along with the presence of the hydrophobic polymer PVDF. Superhydrophobic surfaces over which water contact angles exceed 150° and water roll-off angles are below 10° are considered self-cleaning In contrast to being superhydrophobic, surfaces over which water contact angles are as high as 120° (Teflon®, for example) are considered hydrophobic.

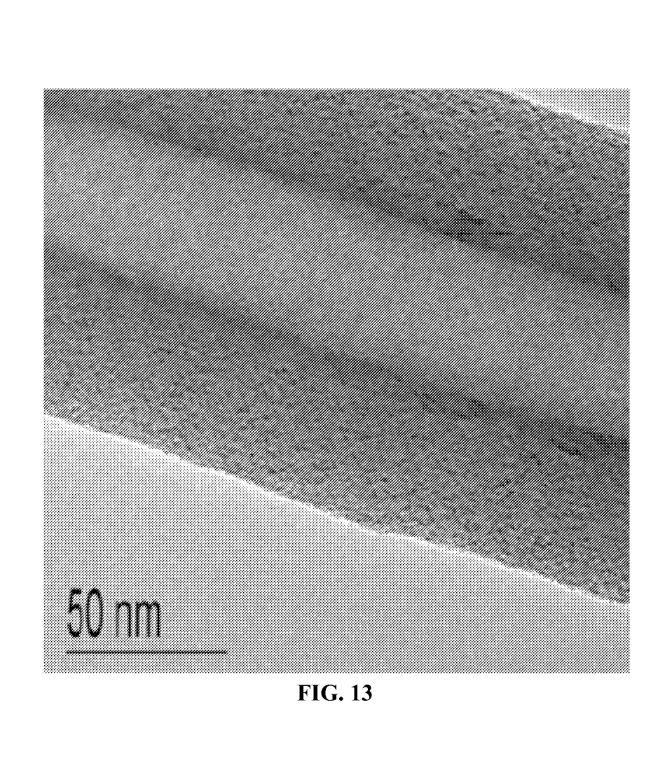

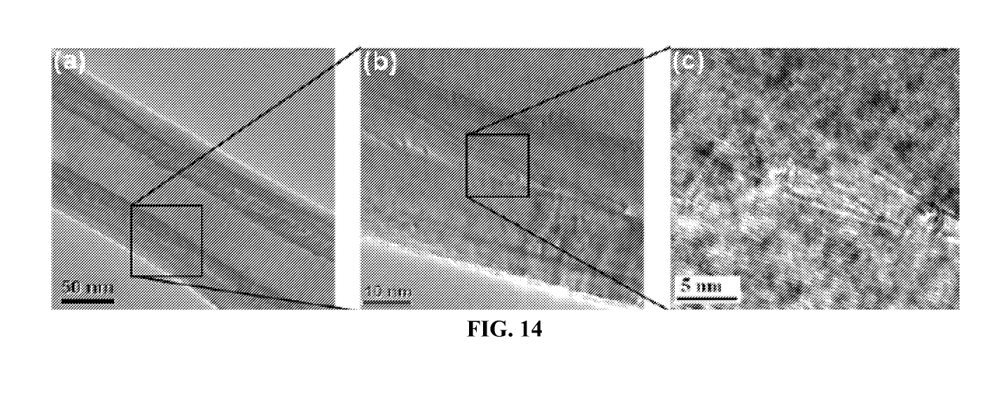

Carbon nanofibers (CNFs) are long, cylindrical carbon nanostructures comprising a diameter of about 100 nm, or between about 25 nm and about 500 nm. The CNFs comprise a length of greater than about 10 μm, for instance greater than 30 μm. In embodiments of the invention, the polymeric composites comprise heat-treated, vapor-grown CNFs, which have reduced amorphous carbon content and higher electrical conductivity compared to as-grown fibers [9]. The amorphous chemical vapor deposition (CVD) carbon of as-grown fibers organizes in graphitized stacked cup and cone structures with heat treatment, such as at 2900° C. for a time of 4 hours. The presence of the organized carbon results in improved electrical conductivity of the CNFs. FIG. 13 shows a transmission electron microscope (TEM) image of as-grown CNFs, while FIG. 14 shows TEM images and high-magnification details of their heat-treated derivatives. The heat treated CNFs show distinct morphological features, such as loop structures on the inner and outer walls, graphitic atomic layers or crystal layers, and nested cone structures. Such features form electrically-conducting elements spanning a wide range of length scales.

In aspects of the invention, for incorporation into a polymeric matrix, CNFs are sonicated in a suitable dispersing solvent before adding the CNFs to a solution comprising PVDF and PMMA. Similar to PTFE particles, suitable dispersing solvents include, without limitation, acetone and acetone/DMF mixtures. The suspended CNFs and PTFE particles are optionally combined prior to addition to a solution blend of PVDF and PMMA.

A solution blend of PVDF and PMMA forms the composite polymer matrix, which has a good degree of hydrophobicity (owing to the presence of PVDF) and interfacial adhesion properties (owing to the presence of PMMA). The environmental durability, hydrophobicity and electroactivity of PVDF, combined with its chemical inertness, make PVDF an ideal choice for the hydrophobic component in the binder polymer, while adhesion and particle dispersion is imparted by the acrylic PMMA. In contrast to the properties of the polymer matrix, PMMA on its own generally forms brittle coatings with much lower mechanical flexibility and stress bearing capacity [23]. Submicron PTFE particles are employed as hydrophobic fillers to tune the coating microstructure and reduce surface energy [24], whereas the electrical conductivity is manipulated using heat-treated, vapor-grown carbon nanofibers (CNFs) [10, 25]. Added functionalities, such as chemical inertness and liquid-repellency, further contribute to the value of polymer-based dried coatings by preventing contamination and corrosion when exposed to outdoor conditions.

It was discovered that the polymeric composite compositions according to the invention are capable of providing effective EMI shielding without sacrificing liquid-repellency, in the frequency ranges of 8.2 GHz to 12.4 GHz and 570 GHz to 630 GHz. Polymeric composite compositions according embodiments of the invention may thus be capable of providing effective EMI shielding in the frequency ranges of 5 GHz to 650 GHz, or 5 GHz to 100 GHz, or 450 GHz to 650 GHz, or 100 GHz to 500 GHz, or 200 GHz to 400 GHz, or a combination of any of the frequency ranges.

In certain embodiments of the invention, the polymer composite compositions are non-metallic. As used herein, the term “non-metallic” refers to polymer composite compositions in which conductivity is provided by materials other than metals, for example and without limitation, carbon nanofibers, carbon nanotubes, and carbon black. According to alternate embodiments of the invention, the polymer composite compositions optionally further comprise microfillers and/or nanofillers that contain metals, for example and without limitation, particles of Cu, Zn, Ti, etc. Further, the inclusion of other fillers, such as Hydroxyapatite, clay or various other polymer powder fillers, such polyetheretherketone (PEEK) or polyethylene (PE), would add additional functionality (e.g., tuning the surface energy of films from partially hydrophilic to super hydrophobic) and enhanced high temperature resistance.

It is believed that such novel PVDF-PMMA composite compositions comprising PTFE particles and CNFs can successfully be employed as functional coatings for numerous applications, for example and without limitation electrostatic dissipation, microwave absorption and electromagnetic interference (EMI) shielding of sensitive electrical/electronic circuitry and devices, antenna systems, aerospace and military equipment (e.g. lightning-protection aircraft composite panels), stealth technology, radar absorbing materials, and avionics line replaceable unit (LRU) enclosures.

Another application for embodiments of the inventive polymer composite compositions is use of the polymer composition as a skin heater. For example, in certain embodiments, a coating of the polymer composite comprising PVDF/PMMA/PTFE/carbon nanofibers is applied to a non-conducting substrate and dried to form a film on the substrate. Due to the conductivity of the coating, when a voltage is applied, the film will heat up and transfer heat to the skin of the substrate. One example for a use of the polymer composite coatings as a heater involves an object that is subject to undesirable freezing conditions, such as an aircraft wing. It would be advantageous to apply heat by means of a conductive composite film coated on the various surfaces of an aircraft, e.g., to at least partially melt and dislodge the ice that had formed over that surface.

The polymer composite compositions according to embodiments of the invention may be applied as a coating to a substrate in an open-air well ventilated environment, for example, by low-cost methods, such as drop casting, spin coating, dip coating, and spray casting. Any suitable casting equipment may be employed to coat the composition onto a substrate, for example an industrial grade internal mix airbrush atomizer (ANEST IWATA, USA Inc., Westchester, Ohio). Further, any substrate that is sufficiently clean to allow good adhesion of the coating may be used. A notable advantage of this coating technique is that it may be performed by a regular spraying process, which is uniquely suited to large area coating applications.

Coatings according to aspects of the invention comprise a thickness of from about 10 μm to about 100 μm. Electromagnetic shielding increases with the thickness of the coating; however, the maximum coating thickness can be limited by reaching a point where delamination of the coating from the substrate occurs. Moreover, material costs also increase with coating thickness.

An advantage of the polymeric composite compositions of the present invention is that they are robust. In particular, films formed from the composites can withstand mechanical stress and still remain adhered to a substrate and maintain their hydrophobic or superhydrophobic characteristics. In addition, the materials involved in the coatings described herein are fairly inexpensive, making the process scalable and economically feasible. Therefore, these techniques can be developed into versatile, industrially feasible, low cost methods to produce dried coatings with tunable surface energies for a broad range of applications.

It should be understood that the term “about” is used throughout this disclosure and the appended claims to account for ordinary inaccuracy and variability in measurement.

The following examples are illustrative of embodiments of the present invention, as described above, and are not meant to limit the invention in any way.

### EXAMPLES

Water droplet sessile contact angle, roll-off angle and electrical conductivity measurements were performed on dried coatings applied on glass microscope slides, as described in detail in the Examples below. EMI shielding measurements were performed over the frequency range of 8.2-12.4 GHz (X-band) on identical coatings applied on cellulosic paper substrates, which in their uncoated state, have typical thickness of ˜100 μm. The underlying hypothesis was that dried coatings, deposited on either glass or paper, would have similar properties and structure when applied under identical conditions. Additionally, large-area carbon nanofiber/PTFE polymer composite coatings were synthesized and tested for effectiveness as attenuators of THz radiation, in particular with respect to EMI shielding effectiveness in the 570 GHz-630 GHz frequency range. The coatings were fabricated by a simple method of spraying dispersions of vapor-grown CNFs and sub-micron PTFE particles in a polymer blend solution of poly(vinylidene fluoride) (PVDF) and poly(methyl methacrylate) (PMMA) on cellulosic substrates. In aspects of the invention, the composition was coated onto the substrate in ambient air, followed by drying to form a film.

### Example 1

Embodiments of the invention comprise preparation of polymeric composite compositions comprising selected loadings of fillers. In Example 1, 60/40 weight percent (wt. %) solution blends of PVDF (530 kDa; Sigma-Aldrich, USA) and PMMA (996 kDa; Sigma-Aldrich, USA) were prepared by mixing 20 wt. % solution of PVDF in Dimethylformamide (DMF) with 10 wt. % solution of PMMA in acetone. Six polymeric composite compositions comprising specific loadings of CNFs having an average fiber diameter of 100 nm (PR24XT-HHT Pyrograf III; Applied Sciences Inc., USA) were prepared, having weight ratios of PVDF/PMMA polymer blend solution to CNF of 1:0.068, 1:0.138, 1:0.281, 1:0.587, 1:0.921 and 1:1.1. The CNFs were free of CVD carbon, with highly graphitized structures developed by high temperature treatment, resulting in higher electrical and thermal conductivity compared to as-grown fibers [26]. In each composition, submicron PTFE particles having an average diameter of 260 nm±54.2 nm (Sigma-Aldrich, USA) were added in an amount to provide a weight ratio of PVDF/PMMA polymer blend solution to PTFE particles of 1:5.76.

PTFE particles and CNFs were sonicated in separate solvents (acetone or acetone/DMF mixtures, respectively) before adding them to the PVDF/PMMA solution. According to certain aspects of the invention, DMF is a preferred dispersant for CNF solvation [27]. However, it was found that excessive amounts of DMF in the sprayed solution tended to reduce surface roughness of the coatings due to the relatively slow evaporation rate of DMF, for instance as compared to acetone. Thus, to maintain adequate surface roughness for achieving the desired hydrophobicity, the CNFs were suspended in pure acetone for the low CNF loading coatings (i.e., 0.068, 0.138, 0.281 and 0.587), and in 20/80 wt. % DMF/acetone at the higher CNF loadings (i.e., 0.921, 1.1).

The PTFE/CNF suspensions were made by combining the corresponding filler dispersions under continuous sonication and were subsequently filtered with a syringe filter comprising a pore size of 20 μm to remove any large agglomerates, before being added directly to the solution blend of PVDF/PMMA for subsequent spray application. A Paasche® airbrush mounted onto a programmable spray robot (Ultra TT series-EFD®, Nordson, USA) was used for spray deposition. After application of the sprayable solutions on glass and cellulosic substrates, the coatings were heat-dried at 90° C. for 1.5 hours to remove any residual solvent. The composite films were superhydrophobic and had electrical conductivities spanning over six orders of magnitude for the following weight composition range: Polymer matrix/PTFE/CNF 1/5.76/0.068-1.1.

### Example 2

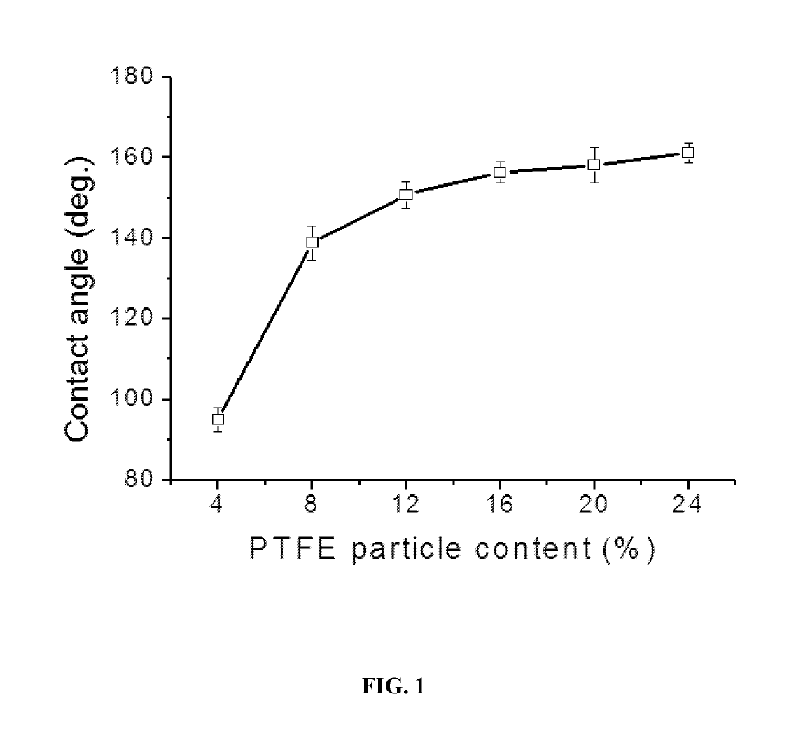

The optimal amount of PTFE filler particles in PVDF/PMMA polymer matrices for attaining superhydrophobicity was determined through wettability tests on dried coatings without CNFs. A 60/40 PVDF/PMMA blend was the binder, and the corresponding PTFE/(PVDF+PMMA) weight ratio varied in the range of 1:1.44-8.64. FIG. 1 shows that for films comprising a PTFE particle content above 16 wt. %, water sessile contact angles exceeded 150°, indicating this as the minimum concentration for superhydrophobic behavior. For 16 wt. % PTFE loading, PTFE/(PVDF+PMMA) has a weight ratio of 1:5.76, and the dried coating is superhydrophobic, more specifically exhibiting a sessile water contact angle of 158°. This minimum PTFE/(PVDF+PMMA) weight ratio to achieve superhydrophobicity of 1:5.76 was kept fixed when preparing composite coatings containing CNFs.

The amount of PTFE particles suitable for the polymer composite composition is expressed either as a weight percent of the entire composition or as a weight ratio with respect to the polymer matrix. According to embodiments of the invention, the amount of PTFE particles comprises between 85 wt. % and 70% of total weight. Alternatively, in aspects of the invention, the amount of PTFE particles comprises a ratio of PTFE particles to polymer matrix of about 5.76:1. Advantageously, a desired level of hydrophobicity is achieved by adjusting the weight percent of PTFE particles in the inventive polymer composite compositions.

### Example 3

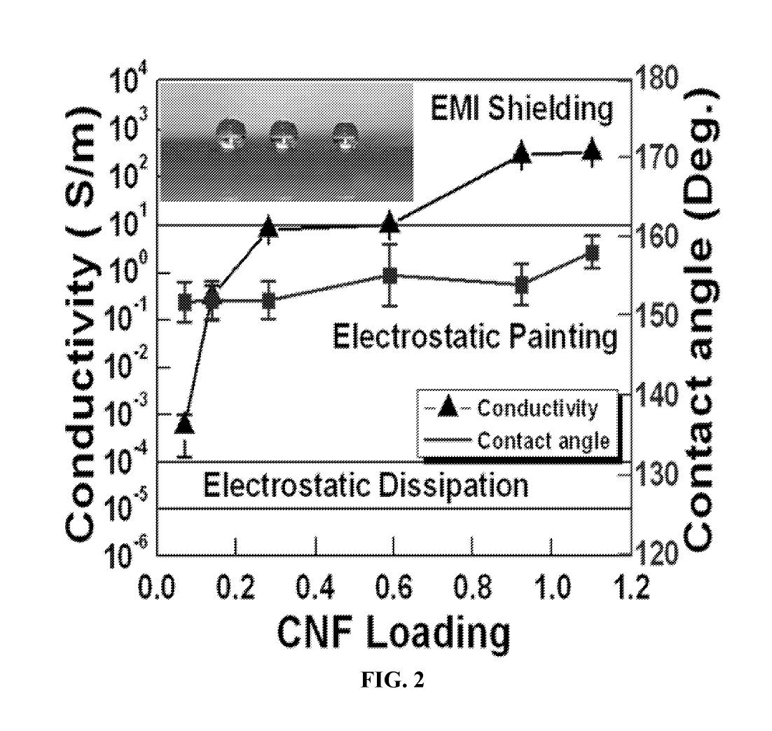

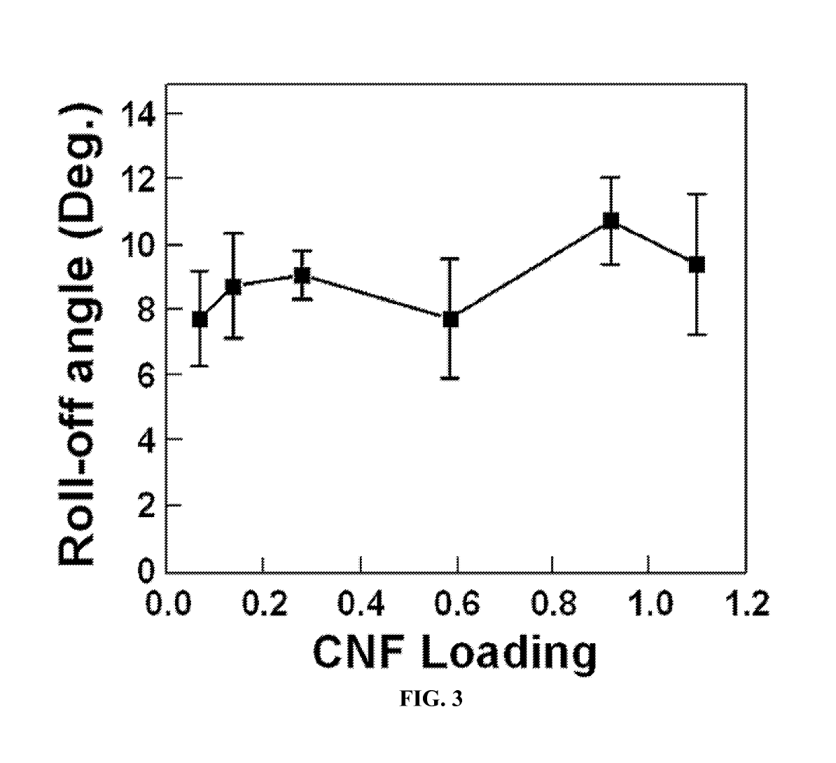

Hydrophobicity and conductivity were tested for polymer composite films according to embodiments of the invention. Water droplet contact and roll-off angle measurements were performed using an in house goniometer-type optical setup described previously [24]. FIG. 2 shows the results of wettability tests and conductivity measurements for dried composite coatings with different CNF loadings expressed in terms of CNF/polymer weight ratios. As shown in FIG. 2, static water contact angles for all CNF loadings remained above 150°. At the maximum CNF loading of 1.1, the measured contact angle reached a value of 158°. As noted in Example 2 above, the corresponding contact angle for CNF-free coating was 158°, which indicates that liquid-repellency is not contingent on the presence of CNFs. Self-cleaning is promoted by low roll-off angles, when the water droplet carries impurities off the tilted surface. FIG. 3 shows that water droplet roll-off angles for all CNF loadings remained close to or below 10°, confirming the self-cleaning liquid-repellent nature of these films.

### Example 4

The dried coating thicknesses of composite coatings according to the invention were measured using an optical microscope calibrated for depth measurement of the top versus bottom of the film. At least three different thickness measurements at different locations were performed on each sample to assess point-to-point thickness uncertainty. The typical dried coating thickness was determined to be near 100 μm.

The electrical conductivities of dried composite coatings according to the invention were measured. The electrical conductivity of the ˜100 μm-thick coatings applied on glass slides was measured using a Keithley 6517 electrometer/ammeter and the two-probe method. The film areas slated for contact with the measuring probes were coated with a conductive silver paint to ensure good electrical contact. A Lab-view based program was used to generate I-V curves and extract the electrical resistance of the dried coatings, which was then used to determine conductivity using the measured values of the coating thickness, width and length.

Referring to FIG. 2, measured electrical conductivity is shown for various (PVDF+PMMA)/PTFE/CNF composite films as a function of CNF loading, expressed in terms of CNF/(PVDF+PMMA) weight ratio. In all cases the PTFE/polymer weight ratio was 5.76. The conductivity regimes suitable for different applications are marked by the horizontal lines in the graph in FIG. 2.

As expected, FIG. 2 shows an increase in conductivity of the dried composite coatings with rising content of conductive CNFs. It can be seen that the electrical percolation threshold for the coatings falls within the 0.068-0.138 CNF loading range, which corresponds to a CNF content of 1-2 wt. % of the total weight of the composite composition. This range is well below the theoretical values calculated for spherical particle fillers [28], and, without wishing to be bound by theory, it is believed that the reason for this difference is the high aspect ratio of CNFs [29]. In addition, FIG. 2 also delineates the required electrical conductivities for three different applications of conductive coatings using two horizontal lines [30]. Achievement of EMI shielding requires a conductivity within the highest conductivity (i.e., top) band. Various electronic products, for instance, require protection of their internal circuitry and magnetic memory based components (e.g., microchips or ICs) from interference of outside electromagnetic fields. Materials with higher values of conductivity can block incoming electromagnetic waves more effectively.

On the other hand, for electrostatic dissipation, which is represented by the low band in FIG. 2, lower conductivities suffice to reduce charge accumulation on insulator surfaces to avoid damage through electrostatic discharge. Similarly, regarding electrostatic painting, materials of moderate to high conductivity are deposited on substrates by electrostatic attraction, which is represented by the middle band in FIG. 2. Corrosion resistant and conductive lightweight polymer coatings in the automobile industry offer one such example. The conductivity values achieved by the inventive compositions and dried coatings are above the electrostatic dissipation range and can reach into the EMI shielding range.

It is clear from FIG. 2 that CNF loading can be used as a tuning parameter to vary the conductivity of the compositions by more than five orders of magnitude without compromising superhydrophobicity. A maximum conductivity value of 309 S/m was obtained for dried coatings with CNF loadings around 1. This underscores the potential of such compositions for numerous applications, and especially EMI shielding. The capability for tuning of EMI shielding by polymer composite compositions of the invention allows for preparation of polymer composite coatings that permit certain frequencies of electromagnetic radiation to be transmitted through the coating while shielding other selected frequencies of electromagnetic radiation. According to embodiments of the invention, dried polymer composite coatings are provided comprising a conductivity value of between about 10⁻⁴ S/m and 10⁴ S/m.

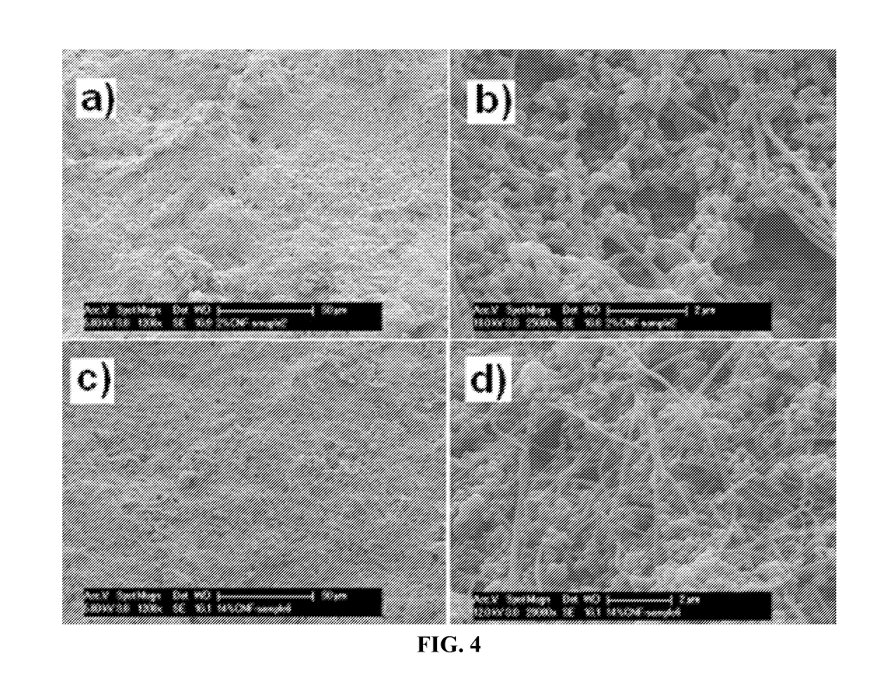

Referring to FIG. 4, scanning electron micrographs are provided of the surface morphology of inventive composite composition films for the two extreme CNF loadings studied. FIGS. 4a and 4b correspond to CNF loadings of 0.068 and FIGS. 4c and 4d to CNF loadings of 1.1. In both cases, a good dispersion of PTFE particles and CNF was achieved within the polymer blend matrix. As noted above, more than a fifteen-fold increase in CNF loading did not alter the degree of superhydrophobicity of the dried coatings (see FIG. 2), although their surface morphology was altered from predominantly PTFE clustered spheres with some CNF strands to a mix of PTFE spheres and nanofibers, as indicated by a comparison of FIGS. 4b and 4d. No phase separation or segregation of the particles was observed even for the highest CNF loading. Moreover, micro to nanoscale surface features were preserved in both cases.

Without wishing to be bound by theory, it is believed that the main factor responsible for the good dispersion of PTFE and CNF, as well as the preservation of the rough surface features responsible for water repellency, is the existence of the PVDF/PMMA polymer blend matrix. Individually, PVDF is a low-interfacial-energy inert polymer, hence particle dispersion within PVDF is rather challenging. Use of pristine PMMA polymer, on the other hand, can result in coatings with brittle and flaky structure and morphology [31] although PMMA is compatible with the filler particles due to its high interfacial energy. To this end, the 60/40 PVDF/PMMA blend was found to be optimal for maintaining a good degree of filler dispersion and high hydrophobicity.

### Example 5

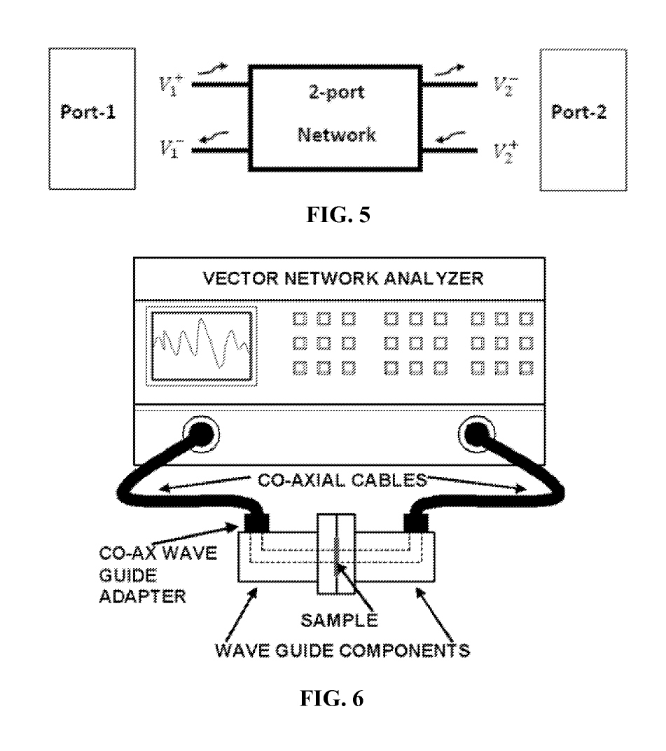

The EMI shielding effectiveness of the dried coatings was measured through S parameter measurements in a two-port configuration [32] using an HP 8719D vector network analyzer (VNA) having an operating range of 50 MHz-13.5 GHz. An in-house assembly consisting of two opposing WR-90 waveguides coupled together to fully encase one coated sample at a time was used to evaluate the EMI shielding performance of the coatings, as represented in the schematic shown in FIG. 5. The capability of a thin planar barrier, for instance a film, to provide shielding from electromagnetic waves was measured in terms of its signal attenuation, defined [33] as

$$10 log \vert \frac{{P}_{i}}{{P}_{t}} \vert = 20 log \vert \frac{{E}_{i}}{{E}_{t}} \vert [ dB ] , \qquad ( 1 )$$

where Pᵢ is the incident power on one side of the barrier and Pᵢ is the power transmitted through the barrier to the other side. The power ratio may also be expressed in terms of the ratio of the magnitudes of the incident electric field Eᵢ and transmitted electric field Eₜ by assuming that the fields are plane waves. Moreover, this same ratio can be expressed in terms of the ratio of voltages associated with the ports of an appropriate network, and thus be determined through S parameter measurements [34]. In general, systems that carry electromagnetic waves may be given a simpler description by treating them as networks and focusing only on the exchange of electromagnetic energy at their ports. According to Eq. (1), which is specific to transmission, the lower the value in decibels, the higher the signal attenuation, and in turn, the higher the shielding effectiveness of the barrier. A similar expression to Eq. (1) can be defined for signal reflection, which was also studied.

### Example 6

The S parameters for dried coatings with different CNF loadings were measured to determine EMI shielding of inventive polymer composite films. For a two-port network, as shown in FIG. 5, the incident (+) and reflected (−) waves at ports 1 and 2 are related through

$$[ \begin{matrix}{V}_{1}^{-} \\ {V}_{2}^{-}\end{matrix} ] = [ \begin{matrix}{S}_{11} & {S}_{12} \\ {S}_{21} & {S}_{22 }\end{matrix} ] [ \begin{matrix}{V}_{1}^{+} \\ {V}_{2}^{+}\end{matrix} ] ,$$

where the elements Sᵢⱼ are the S parameters. When the two-port network is connected so that V₁⁺ and V₂⁺ are incident signals reaching ports 1 and 2, respectively, the S parameters measure the reflected signals S₁₁=V₁⁻/V₁⁺ and S₂₂=V₂⁻/V₂⁺ as well as the transmitted signals S₁₂=V₁⁻/V₂⁺ and S₂₁=V₂⁻/V₁⁺.

Using the experimental setup shown in FIG. 6, the measurement of the S parameters provided information on the shielding effectiveness of the inventive dried polymer composite coatings. Specifically, the incident signal comes from port 1 of the vector network analyzer and the portion of this signal that is reflected back is used to determine S₁₁, while the portion of the incident signal that is transmitted through the material and appears at port 2 is used to determine S₂₁. Both S₁₁ and S₂₁ are expressed in decibels (dB), in order to comply with Eq. (1).

Paper substrates, coated with composite films containing different CNF loadings were mounted inside the flange of one of two mating rectangular waveguides, as shown schematically in FIG. 6. At the beginning of each test sequence, a full two-port VNA calibration was performed using an HP X11644A WR-90 calibration tool in the 8.2-12.4 GHz frequency range, in order to introduce the reference boundary conditions, i.e. open, short, load terminations, as well as transmission. All subsequent measurements in a test run were based on these reference values.

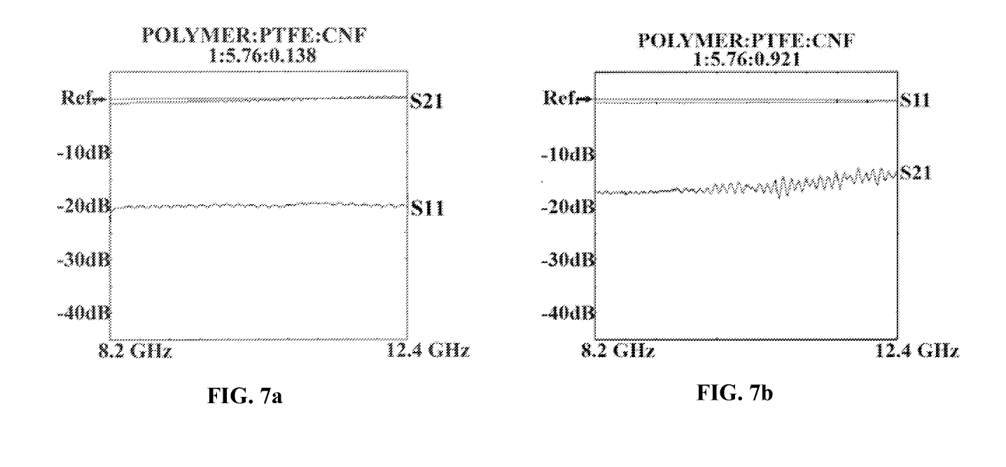

FIG. 7 shows the shielding (S) parameters, S₁₁ (reflection) and S₂₁ (transmission), for two different film samples in the 8.2-12.4 GHz frequency range. The S values were obtained using the two-port measurement setup shown in FIG. 6. FIG. 7a shows the measured shielding parameters of a low-CNF-content film having a ratio of (PVDF+PMMA)/PTFE/CNF of 1:5.76:0.138. FIG. 7b shows the measured shielding parameters of a high-CNF-content film having a ratio of (PVDF+PMMA)/PTFE/CNF of 1:5.76:0.921.

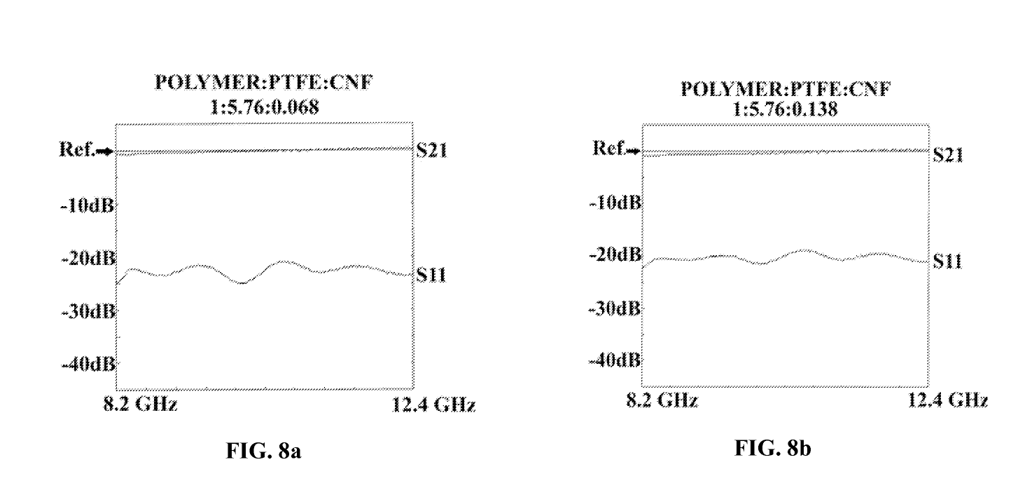

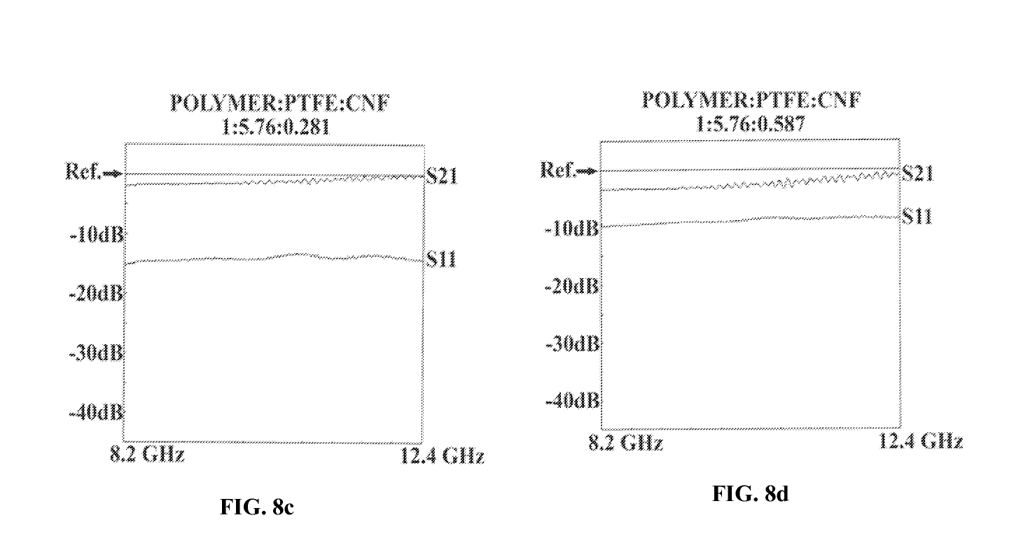

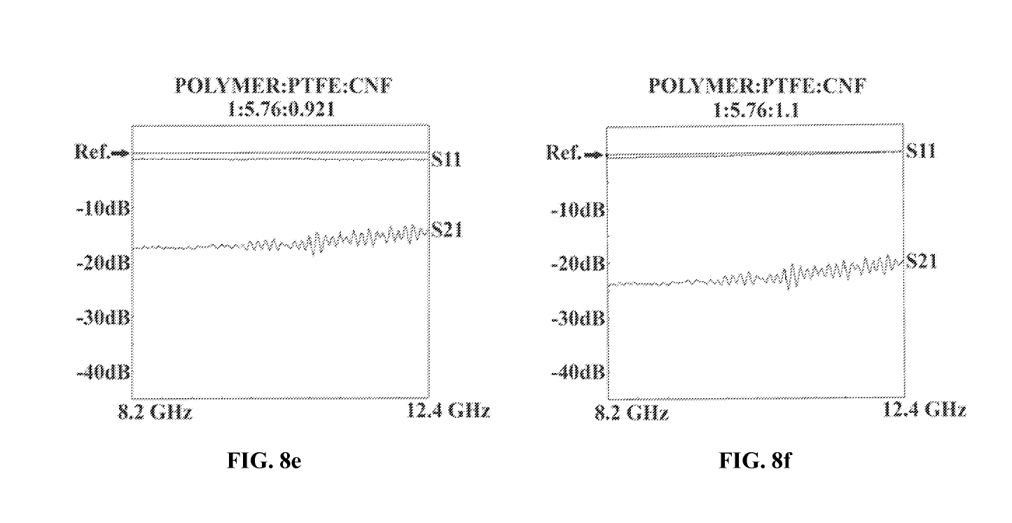

S₁₁ quantifies reflection from the dried coatings, while S₂₁ quantifies transmission through them. The S parameter measurements for dried coatings with different CNF loadings were determined, as shown in FIG. 8. FIG. 8a shows the measured shielding parameters of a low-CNF-content film having a ratio of (PVDF+PMMA)/PTFE/CNF of 1:5.76:0.068. FIG. 8b shows the measured shielding parameters of a low-CNF-content film having a ratio of (PVDF+PMMA)/PTFE/CNF of 1:5.76:0.138. FIG. 8c shows the measured shielding parameters of a low-CNF-content film having a ratio of (PVDF+PMMA)/PTFE/CNF of 1:5.76:0.281. FIG. 8d shows the measured shielding parameters of a high-CNF-content film having a ratio of (PVDF+PMMA)/PTFE/CNF of 1:5.76:0.587. FIG. 8e shows the measured shielding parameters of a high-CNF-content film having a ratio of (PVDF+PMMA)/PTFE/CNF of 1:5.76:0.921. FIG. 8f shows the measured shielding parameters of a high-CNF-content film having a ratio of (PVDF+PMMA)/PTFE/CNF of 1:5.76:1.1.

Through these measurements, it was observed that the 2-port network under test is reciprocal, i.e., S₁₁=S₂₂ and S₁₂=S₂₁, which means that the EMI shielding effect of the present dried composite coatings is similar at their front or back side. To confirm the repeatability of the tests, S parameter values were measured for different coated samples (i.e., batches) prepared with the same CNF loading. Batch-to-batch variations for S were found to be within 10%.

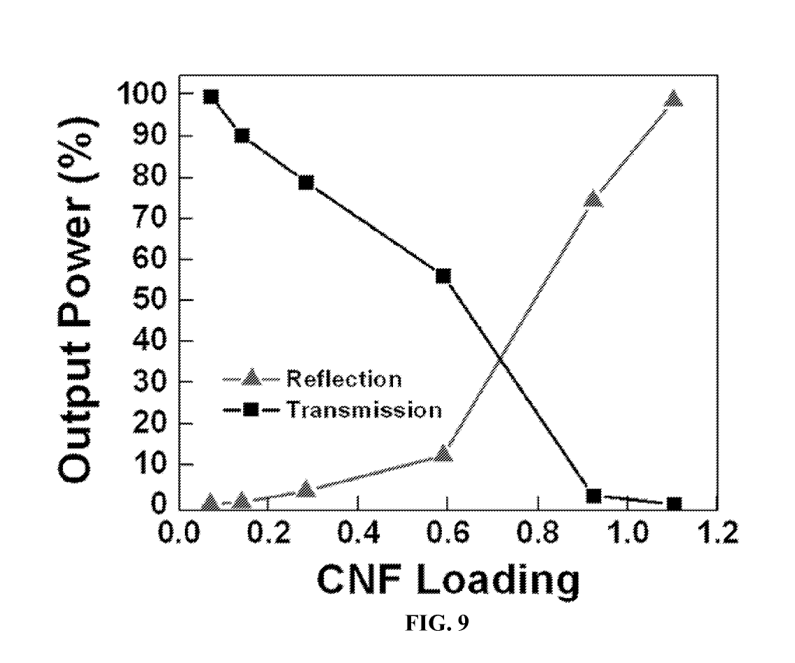

S parameter values can be used to calculate the transmitted and reflected power as a percentage of input wave power in the two-port configuration. The average reflected and transmitted power output (i.e., percent of input power) for different dried coatings with varying CNF loading are thus plotted in FIG. 9, which indicates that as CNF loading rises, the reflected power output rises, hence the absolute value of S₁₁ decreases. This is evident from the values of S₁₁ in FIGS. 8a-8f. When reflected power increases, it automatically lowers transmission, as absorption by these very thin films is expected to be negligible. This is confirmed by the increasing absolute value of transmission parameter S₂₁ at higher CNF loadings in FIG. 8.

S₂₁ (in units of dB) is the negative shielding effectiveness of the dried coatings and increases in absolute value with increasing CNF loading, as shown in FIG. 8. The maximum measured attenuation achieved through the tested inventive films was ˜25 dB in the measured frequency range of 8.2-12.4 GHz, which is a frequency range used by many radar systems, in particular for coatings with the highest tested CNF loading of 1.1. The percentage of transmitted power dropped from nearly 100% to 0.5% as CNF loading was increased from 0.068 to 1.1. An important outcome of the measurements shown in FIG. 8 was that both transmission and reflection parameters S₁₁ and S₂₁ remain fairly flat in the frequency range 8.2-12.4 GHz. This is an indication that the inventive polymer composite coatings are equally effective in shielding over this entire frequency range. Accordingly, in aspects of the invention, polymer composite compositions are provided wherein the film attenuates over 99% of electromagnetic radiation having a frequency range of about 5 GHz to about 15 GHz, or of 8.2 GHz to 12.4 GHz.

### Example 7

Polymeric composite coatings were prepared for determination of EMI shielding at frequencies between 570 GHz and 630 GHz. To prepare the composite coatings, 60/40 wt. % solution blends of PVDF (530 kDa; Sigma-Aldrich, USA) and PMMA (996 kDa; Sigma-Aldrich, USA) were prepared by mixing 20 wt. % solution of PVDF in Dimethylformamide (DMF) with 10 wt. % solution of PMMA in acetone. PTFE particles having an average diameter of 260 nm±54.2 nm (Sigma-Aldrich, USA) were dispersed by sonication in acetone at 0.2 wt. %, while CNFs having an average fiber diameter of 100 nm (PR24XT-HHT Pyrograf III; Applied Sciences Inc., USA) were suspended in pure acetone to produce coatings with CNF/(PVDF+PMMA) weight ratios of 0.068, 0.138 or 0.281, and in 20/80 wt. % DMF/acetone for coatings with CNF/(PVDF+PMMA) weight ratios of 0.587, 0.921, or 1.1 [9]. The separate PTFE and CNF dispersions were combined under continuous sonication. The three PTFE/CNF dispersions with the highest content of CNFs (i.e., 0.587, 0.921 and 1.1) were filtered with a 20 μm syringe filter to remove any large agglomerates before being added to the solution blend of PVDF/PMMA for subsequent spray application on cellulosic substrates. A Paasche® airbrush mounted onto a programmable spray robot (Ultra TT series-EFD, Nordson, USA) was used in this step. The sprayed dispersions were heat-dried at 90° C. for 1.5 hours to remove any residual solvent.

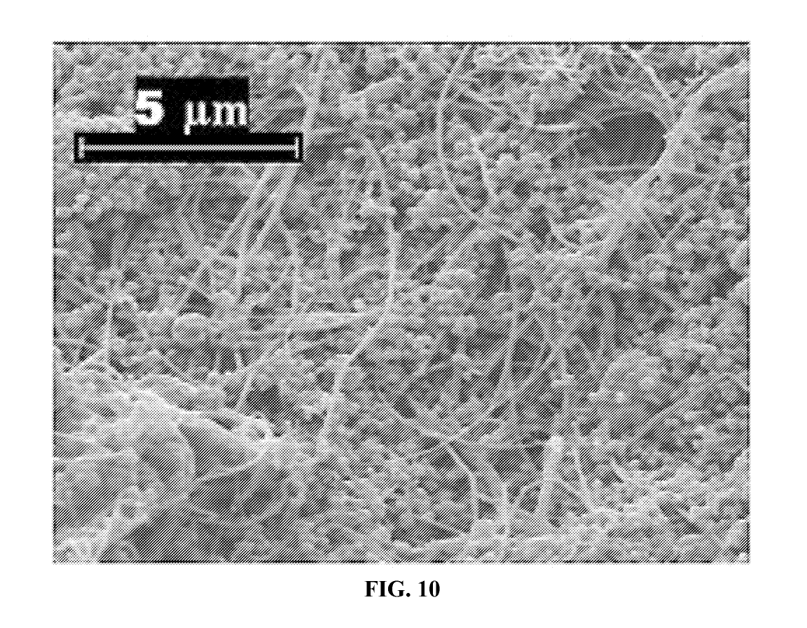

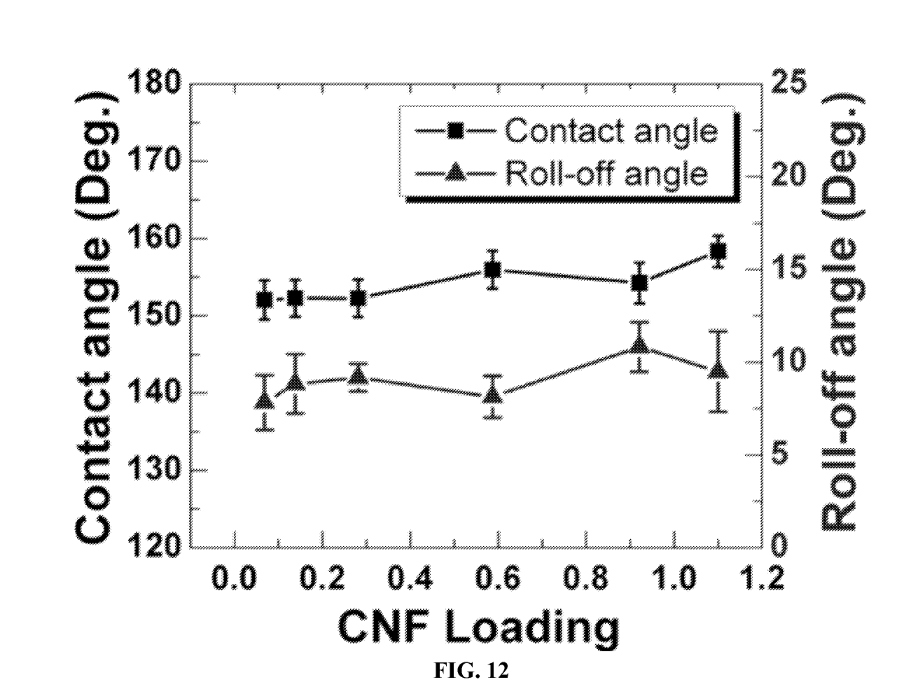

Upon drying, the films exhibited static water contact angles above 150°, demonstrating the superhydrophobicity of the inventive coatings. Moreover, the dried coatings exhibited droplet roll-off angles near or below 10°, indicating self-cleaning ability (i.e., water droplets roll off the inclined surface, thus removing impurities). The weight ratio of PTFE filler particles in the PVDF+PMMA polymer matrix was again PTFE/(PVDF+PMMA)=5.76, and was kept fixed. As shown in FIG. 10, the composite films displayed surface morphologies dominated by clusters of PTFE particles and CNFs in the polymer matrix. Water droplet contact and roll-off angle measurements were performed using a goniometer-type optical setup [24]. The results are displayed in FIG. 12, where static water contact angles remained above 150° for all CNF loadings. The corresponding contact angle for CNF-free coatings was 158° [9], indicating that super-repellency is not contingent upon the presence of CNFs. Water droplet roll-off angles remained close or below 10°, confirming the self-cleaning nature of these films.

### Example 8

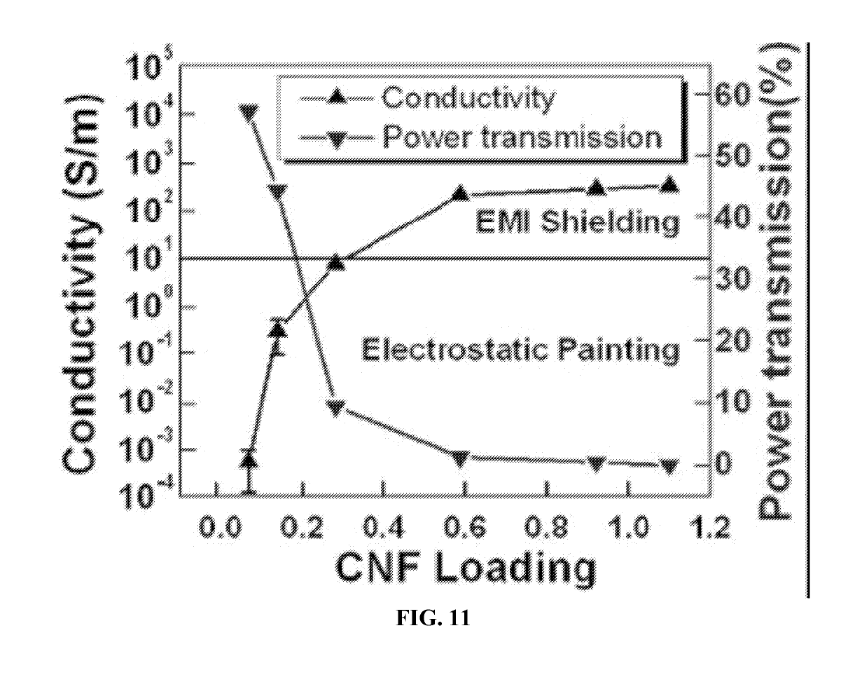

This surface structure resulted in high liquid repellency and electrical conductivities spanning over six orders of magnitude for the following weight composition range: Polymer matrix/PTFE/CNF 1/5.76/0.068-1.1 [9]. The film areas slated for contact with the measuring probes were coated with a conductive silver paint to ensure good electrical contact. I-V curves were generated to extract the electrical resistance of the dried coatings, which was then used to determine conductivity using the measured values of the film thickness, width and length. Electrical conductivity of the dried coatings rose with CNF loading, as shown in FIG. 11. The electrical percolation threshold falls within the 0.068-0.138 CNF loading range, which corresponds to a CNF content of 1-2 wt. % of the total polymeric composition. Although the dried coatings used to produce this graph had the same composition as the coatings in FIG. 2, the conductivities differed because the solvent system was not the same. Accordingly, it should be understood that measured conductivity can be affected by the particular solvent system employed when forming a polymer composite film. The presence of a high boiling point solvent in the dispersion creates smooth thin coatings with higher electrical conductivity for a given amount of solid composite mass.

### Example 9

The dried coating thicknesses of composite coatings according to the invention were measured using an optical microscope calibrated for depth measurement of the top vs. bottom of the coating. At least three different thickness measurements at different locations were performed on each sample to assess point-to-point thickness uncertainty. The film thickness was determined to be between 50 μm and 100 μm.

The electrical conductivities of dried composite coatings according to the invention were measured. The electrical conductivity of identical coatings applied on glass slides was measured using a Keithley 6517 electrometer/ammeter and the two-probe method.

The shielding effectiveness of such dried coatings in the 570-630 GHz frequency range was measured by a frequency domain terahertz spectroscopy instrument [35], which has been previously described [36]. Specifically, THz radiation was provided by a VDI (Virginia Diodes, Inc.) frequency extension module (FEM, or multiplier chain), which converted a microwave (10-20 GHz) signal from a synthesizer to THz radiation in the frequency range of 570-630 GHz. The average output power in this range is approximately 1 mW. The THz energy was coupled to a zero-bias Schottky diode broadband detector [37] through four off-axis parabolic mirrors A-D. For two-dimensional mapping measurements, the source was fixed at one frequency, and the sample was scanned using a 2-D positioning stage. Averaged voltage response data was taken at each position and was then normalized to the detector response without sample. A 2-D attenuation image was reconstructed electronically.

FIG. 13 shows the THz power transmission for six samples with CNF content from 1 wt. % to 14 wt. %. The THz transmittance is shown in dB, or EMI SE is defined by SE (dB)=−10 log₁₀(Pₜᵣₐₙ/P_{inc}), where Pₜᵣₐₙ and P_{inc} are transmitted and incident THz powers. The Schottky detector worked in the square-law region, therefore the output voltage response was proportional to the detected power. The transmittance curves for the first five samples were quite uniform over the entire frequency range, and have been previously reported [36]. The spectra were averaged for each sample over the frequency range to produce the curves drawn in FIG. 11.

The gradually increasing measured average SE of 2.4 dB to 32.0 dB is consistent with the rising CNF content in these samples. The shielding effectiveness of the dried inventive polymeric composite composition at terahertz frequencies was unexpected at least because electromagnetic radiation at terahertz frequencies is known to be more invasive and agile than electromagnetic radiation at lower frequencies. In aspects of the invention, polymer composite compositions are provided, wherein the film attenuates over 99% of electromagnetic radiation having a frequency range of about 570 GHz to 630 GHz.

The coating film uniformity and its effect on shielding property have been studied [36]. 2D scanning measurements were performed for two samples having CNF loadings of 0.281 and 0.921 at 600 GHz. The scanning area was 10 mm×10 mm and the scanning step size was 0.5 mm. For each position, the voltage response of the detector was measured 5 times, and the averaged value was normalized to the response without sample (i.e., control) to calculate the transmittance. The transmittance of the scanned region of the first sample having a CNF loading of 0.281 varied within ˜17.9%. In comparison, the second sample, having a CNF loading of 0.921, showed a much better uniformity of ˜4.1%, which is satisfactory for practical applications. The uniformity of the remaining four samples was closer to the sample with a CNF loading of 0.921, indicating that spatial uniformity of dB attenuation below 10% can be expected using the present methods.

According to embodiments of the invention, the weight ratio of the combined PVDF and PMMA to the PTFE particles to the carbon nanofibers comprises 1:5.76:0.068-5.04. Moreover, in certain aspects, the film comprises an electrical conductivity of about 10 Siemens per meter (S/m) to about 310 S/m. In alternate aspects, the film comprises an electrical conductivity of greater than 310 S/m.

In principle, SE values higher than those already measured [36] could be attained with CNFs of higher conductivity or metallic fillers. There exist different ways [10] to improve the conductivity of vapor grown CNFs, such as acid treatment, carbonization, graphitization, open air etching, etc. Among these processes, graphitization is most effective [10]. Heat treatment of CNFs at 2800° C. results in an electrical resistance of 10⁻⁴ Ωcm due to a higher degree of crystallinity or graphitization [38]. As noted above, the CNFs employed in the inventive compositions have been treated at 3000° C., and were confirmed to display high electrical conductivity, as shown in FIG. 11.

An additional factor contributing to high conductivity at low filler particle loadings is the high aspect ratio of the conductive filler, which lowers the percolation threshold [39]. As used herein, the term “aspect ratio” refers to the ratio of length to diameter. The CNFs used herein have very high aspect ratio (i.e., well over 100), which makes them a good choice as conductive fillers. SE also depends on specific volume and surface area of the conductive fillers [40, 41]. Since most of the shielding is provided by the material up to a short depth from the surface (i.e., skin depth), fillers with high specific volume and surface area should display higher SE [10, 42]. The hollow cavity of the CNFs not only increases their specific surface area and volume, but also enhances internal EM reflection, thus further contributing to their SE [26]. Finally, the CNFs feature conductive elements spanning a wide range of length scales, which promotes broadband attenuation [43], as is evident from the fairly flat SE values [36] in the range 570-630 GHz.

While the invention has been described with respect to specific examples including presently preferred modes of carrying out the invention, those skilled in the art will appreciate that there are numerous variations and permutations of the above described systems and techniques that fall within the spirit and scope of the invention. It should be understood that the invention is not limited in its application to the details of construction and arrangements of the components set forth herein. Variations and modifications of the foregoing are within the scope of the present invention. It is also being understood that the invention disclosed and defined herein extends to all alternative combinations of two or more of the individual features mentioned or evident from the text and/or drawings. All of these different combinations constitute various alternative aspects of the present invention. The embodiments described herein explain the best modes known for practicing the invention and will enable others skilled in the art to utilize the invention. The claims are to be construed to include alternative embodiments to the extent permitted by the prior art.

### REFERENCES

1. Y. Zhu Y, J. Zhang, Y. Zheng, Z. Huang, L. Feng, L. Jiang, Adv. Funct. Mater. 16 (2006) 568.
2. J. T. Han, S. Y. Kim, J. S. Woo, G. W. Lee., Adv. Mater. 20 (2008) 3724.
3. C. Luo, X. Zuo, L. Wang, E. Wang, S. Song, J. Wang, J. Wang, C. Fan, Y. Cao, Nanoletters 8 (2008) 4454.
4. L. Y. Meng, S. J. Park, J. Colloid Interface Sci. 342 (2009) 559.
5. J. Zou, H. Chen, A. Chunder, Y. Yu, Q. Huo, L. Zhai, Adv. Mater. 20 (2008) 3337.
6. Y. L. Yang, M. C. Gupta, K. L. Dudley, R. W. Lawrence, Nano Lett. 5 (2005) 2134.
7. D. C. Trivedi, In: H. S, Nalwa (Eds.), Handbook of Organic Conductive Molecules and Polymers Wiley, New York, 1997, Vol. 2, p. 505.
8. G. G. Tibbetts, M. L. Lake, K. L. Strong, and B. P. Rice. Composites Science and Technology 67, 1709 (2007).
9. A. Das, H. T. Hayvaci, M. K. Tiwari, I. S. Bayer, D. Erricolo, and C. M. Megaridis, Journal of Colloid and Interface Science 353, 311 (2010).
10. M. H. Al-Saleh, U. Sundararaj, Carbon 47 (2009) 2.
11. P. H. Siegel, IEEE Trans. Microwave Theory Tech. 50, 910 (2002).
12. T. R. Globus, M. L. Norton, M. I. Lvovska, D. A. Gregg, T. B. Khromova, and B. L. Gelmont, IEEE Sensors Journal 10, 410 (2010).
13. E. R. Brown, E. A. Mendoza, D. Xia, and S. R. J. Brueck, IEEE Sensors Journal 10, 755 (2010).
14. T. G. Phillips, J. Keene, Proceedings of the IEEE 80, 1662 (1992).
15. L. Liu, H. Xu, A. W. Lichtenberger, and R. M. Weikle, II, IEEE Trans. Microwave Theory Tech. 58, 1943 (2010).
16. T. Crowe, W. Bishop, D. Porterfield, J. Hesler, R. Weikle, IEEE J. of Solid State Circuits 40, 2104 (2005).
17. T. W. Crowe, J. L. Hesler, D. W. Porterfield, D. S. Kurtz, and K. Hui, “Development of multiplier based sources for up to 2 THz,” IRMMW-THz. Joint 32nd International Conference on Infrared and Millimeter Waves and 15th International Conference on Terahertz Electronics, pp. 621-622, 2-9 Sep. 2007.
18. B. S. Williams, Nature Photonics 1, 517 (2007).
19. V. Radisic, W. R. Deal, K. M. K. H. Leong, X. B. Mei, W. Yoshida, P.-H. Liu, J. Uyeda, A. Fung, L. Samoska, T. Gaier, and R. Lai, IEEE Trans. Microwave Theory Tech. 58, 1903 (2010).
20. J. Federici and L. Moeller, Appl. Phys. Lett. 107, 111101 (2010).
21. M. A. Seo, J. H. Yim, Y. H. Ahn, F. Rotermund, D. S. Kim, S Lee, and H. Lim, Appl. Phys. Lett. 93, 231905 (2008).
22. O. Shenderova, V. Grishko, G. Cunningham, S. Moseenkov, G. McGuire, and V. Kuznetsov, Diamond and Related Materials 17, 462 (2008).
23. Z. W. Wicks Jr., F. N. Jones, S. P. Pappas, D. A. Wicks, Organic coatings science and technology. Hoboken: John Wiley & Sons, 2007.
24. M. K. Tiwari, I. S. Bayer, G. M. Jursich, T. M. Schutzius, C. Megaridis, ACS App. Matl. & Inter. 2 (2010) 1114.
25. E. Hammel, X. Tang, M. Trampert, T. Schmitt, K. Mauthner, A. Eder, P. Potschke, Carbon 42 (2004) 1153.
26. S. Yang, K. Lozano, A. Lomeli, H. D. Foltz, R. Jones, Composites: Part A. 36 (2005) 691.
27. Y. J. Yang, G. J. Zhao, S. Hu, Electrochem. Commun. 9, (2007) 2681.
28. D. Stauffer, A. Aharony, Introduction to Percolation Theory, Taylor & Francis, Washington, D.C., 1992.
29. J. K. W. Sandler, J. E. Kirk, I. A. Kinloch, M. S. P. Shaffer, A. H. Windle, Polymer. 44 (2003) 5893.
30. R. Ramasubramaniam, J. Chen, H. Y. Liu, Appl. Phys. Lett. 83 (2003) 2928.
31. I. S. Bayer, M. K. Tiwari, C. M. Megaridis, Appl. Phys. Lett. 93 (2008) 173902.
32. Y. K. Hong, C. Y. Lee, C. K. Jeong, J. H. Sim, K. Kim, J. Joo, M. S. Kim, J. Y. Lee, S. H. Jeong, S. W. Byun, Current Applied Physics. 1 (2001) 439.
33. C. R. Paul, Introduction to electromagnetic compatibility, Hoboken, Wiley-Interscience, 2006.
34. D. M. Pozar, Microwave engineering, Hoboken, John Wiley & Sons, 1998.
35. L. Liu, J. L. Hesler, R. M. Weikle, T. Wang, P. Fay, H. Xing, International Journal of High Speed Electronics and Systems, accepted.
36. A. Das, C. M. Megaridis, L. Liu, T. Wang, and A. Biswas, Appl. Phys. Lett. 98, 174101 (2011).
37. L. Liu, J. L. Hesler, H. Xu, A. W. Lichtenberger, and R. M. Weikle, II, IEEE Microwave and Wireless Components Letters 20, 504 (2010).
38. M. Endo, Y. A. Kim, T Hayashi, K. Nishimura, T. Matusita, K. Miyashita, and M. S. Dresselhaus, Carbon 39, 1287 (2001).
39. T. Prasse, J. Y. Cavaille, and W. Bauhofer, Compos. Sci. Tech. 63, 1835 (2003).
40. B. O. Lee, W. J. Woo, and M. S. Kim. Macromol. Mater. Eng 286, 114 (2001).
41. J. H. Wu and D. D. L. Chung, Carbon 40, 445 (2002).
42. R. M. Bagwell, J. M. McManaman, and R. C. Wetherhold, Compos. Sci. Technol. 66, 522 (2006).
43. V. L. Kuznetsov, Y. V. Butenko, in: D. Gruen, O. Shenderova, A. Vul (Eds.), Synthesis, Properties and Applications of Ultrananocrystalline Diamond, NATO Science Series, Springer, Amsterdam, 2005, p. 199.

We claim:

1. A polymeric composition comprising a blend of poly(vinylidine fluoride) (PVDF), poly(methyl methacrylate) (PMMA), carbon nanofibers, and poly(tetrafluoroethylene) (PTFE) particles.

2. The composition of claim 1, wherein the PTFE particles comprise an average diameter of between about 200 nm and about 300 nm.

3. The composition of claim 1, wherein when the polymeric composition is applied to a substrate and dried to form a film, the film attenuates over 99% of electromagnetic radiation in the frequency range of about 5 GHz to about 650 GHz.

4. The composition of claim 1, wherein when the polymeric composition is applied to a substrate and dried to form a film, the film comprises an electromagnetic interference (EMI) shielding effectiveness of about 32 decibels.

5. The composition of claim 1, wherein when the polymeric composition is applied to a substrate and dried to form a film, the film comprises an electrical conductivity of about 10 Siemens per meter (S/m) to about 310 S/m.

6. The composition of claim 1, wherein the weight ratio of the PVDF to the PMMA comprises about 60:40

7. The composition of claim 6, wherein the weight ratio of the combined PVDF and PMMA to the PTFE particles to the carbon nanofibers comprises about 1:5.76:0.068-1.1.

8. The composition of claim 7, wherein the composition is non-metallic.

9. The composition of claim 1, wherein the composition further comprises at least one solvent selected from the group consisting of Dimethylformamide (DMF) and acetone.

10. A method for making a polymeric film comprising:
a. providing a polymeric composition comprising poly(vinylidine fluoride) (PVDF), poly(methyl methacrylate) (PMMA), carbon nanofibers, and poly(tetrafluoroethylene) (PTFE);
b. coating the composition onto a substrate; and
c. drying the composition to form the polymeric film on the substrate.

11. The method according to claim 10, wherein the composition is non-metallic.

12. The method according to claim 10, wherein the drying comprises heating the composition coated on the substrate at a temperature of at least 90 degrees Celsius for at least 1.5 hours.

13. The method according to claim 10, wherein the film has a water sessile contact angle of at least 150 degrees.

14. The method according to claim 13, wherein the film has a water droplet roll-off angle of at or below ten degrees.

15. The method according to claim 10, wherein the film attenuates over 99% of electromagnetic radiation having a frequency range of about 5 GHz to about 650 GHz.

16. The method according to claim 10, wherein the film comprises a thickness of between about 10 microns and about 100 microns.

17. The method according to claim 10, wherein the film comprises an electromagnetic interference (EMI) shielding effectiveness of about 32 decibels.

18. The method according to claim 10, wherein the film comprises an electrical conductivity of about 10 Siemens per meter (S/m) to about 310 S/m.

19. A coated substrate comprising a substrate and a film adhered to the substrate, the film comprising a polymeric composition comprising a blend of poly(vinylidine fluoride) (PVDF), poly(methyl methacrylate) (PMMA), carbon nanofibers, and poly(tetrafluoroethylene) (PTFE) particles.

20. The coated substrate according to claim 19, wherein the weight ratio of the combined PVDF and PMMA to the PTFE particles to the carbon nanofibers comprises about 1:5.76:0.068-1.1 and wherein the film attenuates over 99% of electromagnetic radiation having a frequency range of 8.2 GHz to 12.4 GHz or having a frequency range of 570 to 630 GHz.
